(19) United States
(12) Patent Application Publication
(10) Pub. No.: US 2012/0252212 A1
(43) Pub. Date: Oct. 4, 2012

(54) PROCESSING METHOD FOR WAFER HAVING EMBEDDED ELECTRODES

(75) Inventor: Yoshiteru Nishida, Ota-ku (JP)

(73) Assignee: DISCO CORPORATION, Tokyo (JP)

(21) Appl. No.: 13/434,385

(22) Filed: Mar. 29, 2012

(30) Foreign Application Priority Data
Mar. 30, 2011 (JP) 2011-075083

(51) Int. Cl. H01L 21/306

(52) U.S. Cl. 438/691; 257/E21.215

(57) ABSTRACT

A wafer processing method which includes a protective member attaching step of attaching a protective member to the front side of the wafer, a back grinding step of grinding the back side of the silicon (Si) substrate of the wafer so as not to expose electrodes to the back side of the silicon (Si) substrate, and an etching step of etching the back side of the silicon (Si) substrate by using an etching liquid to thereby expose the electrodes to the back side of the silicon (Si) substrate. The etching liquid includes a first etching liquid having a high etching rate to silicon (Si) and a second etching liquid capable of etching silicon (Si) and having a low etching rate to silicon dioxide (SiO₂).

### BACKGROUND OF THE INVENTION

1. Field of the Invention

The present invention relates to a wafer processing method for processing a wafer including a silicon substrate and a plurality of devices formed on the front side of the silicon substrate, wherein each device is provided with a bonding pad, and an electrode is embedded in the silicon substrate so as to be connected to the bonding pad.

2. Description of the Related Art

In a semiconductor device fabrication process, a plurality of crossing division lines called streets are formed on the front side of a substantially disk-shaped silicon (Si) substrate to partition a plurality of regions where a plurality of semiconductor devices such as ICs and LSIs are respectively formed, thus obtaining a wafer including the silicon (Si) substrate and the plural semiconductor devices formed on the front side of the silicon (Si) substrate. The wafer is cut along the streets to thereby divide the regions where the semiconductor devices are formed from each other, thereby obtaining the individual semiconductor devices.

For the purposes of achieving smaller sizes and higher functionality of equipment, a module structure having the following configuration is in practical use. This module structure is such that a plurality of devices are stacked and bonding pads provided on each device are connected to each other. In this module structure, via holes are formed in a silicon (Si) substrate at positions corresponding to the bonding pads, and electrodes of copper, aluminum, etc. covered with an insulating material of silicon dioxide (SiO₂) are embedded in the via holes so as to be connected to the bonding pads (see Japanese Patent Laid-open No. 2003-163323, for example). The copper (Cu) electrodes embedded in the silicon (Si) substrate are exposed to the back side of the silicon (Si) substrate by grinding the back side of the silicon (Si) substrate to expose the copper (Cu) electrodes to the back side of the silicon (Si) substrate and next etching the back side of the silicon (Si) substrate by using potassium hydroxide (KOH) having a high etching rate to silicon (Si) and a low etching rate to copper (Cu) as an etching liquid, thereby projecting the copper (Cu) electrodes from the back side of the silicon (Si) substrate by an amount of 5 to 10 μm.

### SUMMARY OF THE INVENTION

However, potassium hydroxide (KOH) has a high etching rate also to silicon dioxide (SiO₂). Accordingly, there is a problem such that the silicon dioxide (SiO₂) film as an insulating film covering the copper (Cu) electrodes is etched by potassium hydroxide (KOH) to cause a reduction in insulation quality between the silicon (Si) substrate and the copper (Cu) electrodes. On the other hand, when tetramethylammonium hydroxide (TMAH) having a low etching rate to silicon dioxide (SiO₂) is used as the etching liquid, there is a problem such that the copper (Cu) electrodes are etched because tetramethylammonium hydroxide (TMAH) has a high etching rate to copper (Cu).

It is therefore an object of the present invention to provide a wafer processing method for processing a wafer having embedded electrodes which can expose the electrodes from the back side of the silicon (Si) substrate without etching the silicon dioxide (SiO₂) film as an insulating film covering the electrodes to cause a reduction in insulation quality and also without etching the electrodes.

In accordance with an aspect of the present invention, there is provided a wafer processing method for processing a wafer including a silicon (Si) substrate and a plurality of devices formed on the front side of the silicon (Si) substrate, wherein each device is provided with a bonding pad, and an electrode covered with a silicon dioxide (SiO₂) film is embedded in the silicon (Si) substrate so as to be connected to the bonding pad, the wafer processing method including a protective member attaching step of attaching a protective member to the front side of the wafer; a back grinding step of grinding the back side of the silicon (Si) substrate of the wafer so as not to expose the electrode to the back side of the silicon (Si) substrate after performing the protective member attaching step; and an etching step of etching the back side of the silicon (Si) substrate by using an etching liquid to thereby expose the electrode to the back side of the silicon (Si) substrate after performing the back grinding step; the etching liquid including a first etching liquid having a high etching rate to silicon (Si) and a second etching liquid capable of etching silicon (Si) and having a low etching rate to silicon dioxide (SiO₂); the etching step having a first etching step of etching the back side of the silicon (Si) substrate by using the first etching liquid to thereby incompletely expose the electrode covered with the silicon dioxide (SiO₂) film to the back side of the silicon (Si) substrate and a second etching step of etching the back side of the silicon (Si) substrate by using the second etching liquid to thereby project the electrode covered with the silicon dioxide (SiO₂) film from the back side of the silicon (Si) substrate after performing the first etching step.

Preferably, the electrode is formed of copper (Cu), the first etching liquid includes a mixture of hydrofluoric acid (HF) and nitric acid (HNO₃), and the second etching liquid includes tetramethylammonium hydroxide (TMAH).

Alternatively, the electrode is formed of copper (Cu), the first etching liquid includes potassium hydroxide (KOH), and the second etching liquid includes tetramethylammonium hydroxide (TMAH).

Preferably, the wafer processing method further includes a polishing step of polishing the back side of the silicon (Si) substrate so as not to expose the electrode to the back side of the silicon (Si) substrate after performing the back grinding step and before performing the etching step, thereby removing a saw mark formed on the back side of the silicon (Si) substrate in the back grinding step.

As described above, the wafer processing method according to the present invention includes the protective member attaching step of attaching the protective member to the front side of the wafer, the back grinding step of grinding the back side of the silicon (Si) substrate of the wafer so as not to expose the electrode to the back side of the silicon (Si) substrate, and the etching step of etching the back side of the silicon (Si) substrate by using the etching liquid to thereby expose the electrode to the back side of the silicon (Si) substrate. The etching liquid includes the first etching liquid having a high etching rate to silicon (Si) and the second etching liquid capable of etching silicon (Si) and having a low etching rate to silicon dioxide (SiO₂). The etching step includes the first etching step of etching the back side of the silicon (Si) substrate by using the first etching liquid to thereby incompletely expose the electrode covered with the silicon dioxide (SiO₂) film to the back side of the silicon (Si) substrate and the second etching step of etching the back side of the silicon (Si) substrate by using the second etching liquid to thereby project the electrode covered with the silicon dioxide (SiO₂) film from the back side of the silicon (Si) substrate after performing the first etching step.

Accordingly, the etching rate to the silicon dioxide (SiO₂) film covering the electrode in the second etching step is low, so that the electrode can be projected from the back side of the silicon (Si) substrate so as not to be etched.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a wafer to be processed by the wafer processing method according to the present invention;

FIG. 2 is an enlarged sectional view of an essential part of the wafer shown in FIG. 1;

FIGS. 3A and 3B are perspective views for illustrating a protective member attaching step in the wafer processing method according to the present invention;

FIGS. 4A to 4C are views for illustrating a back grinding step in the wafer processing method according to the present invention;

FIGS. 5A to 5C are views for illustrating a polishing step in the wafer processing method according to the present invention;

FIG. 6 is a perspective view of an etching apparatus for performing an etching step in the wafer processing method according to the present invention;

FIG. 7 is a sectional side view of the etching apparatus shown in FIG. 6 in the condition where a spinner table is set at a work load/unload position;

FIG. 8 is a view of the etching apparatus shown in FIG. 6, showing the condition where the spinner table is set at a working position;

FIGS. 9A and 9B are views for illustrating a first etching step in the wafer processing method according to the present invention;

FIGS. 10A and 10B are views for illustrating a second etching step in the wafer processing method according to the present invention; and

FIG. 11 is a table showing the etching rates of a mixture of hydrofluoric acid (HF) and nitric acid (HNO₃), potassium hydroxide (KOH), and tetramethylammonium hydroxide (TMAH) to silicon (Si), silicon dioxide (SiO₂), and copper (Cu).

### DETAILED DESCRIPTION OF THE PREFERRED EMBODIMENTS

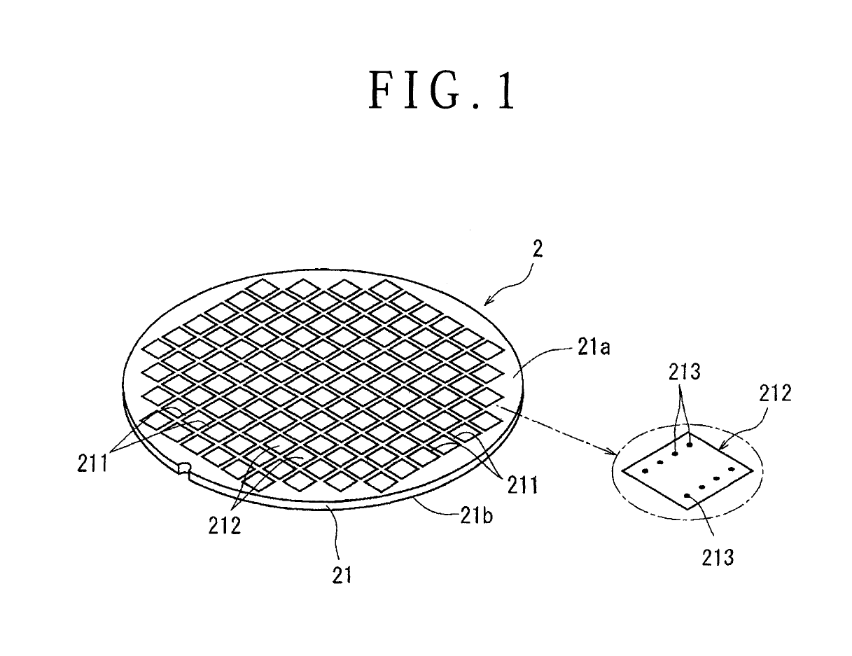

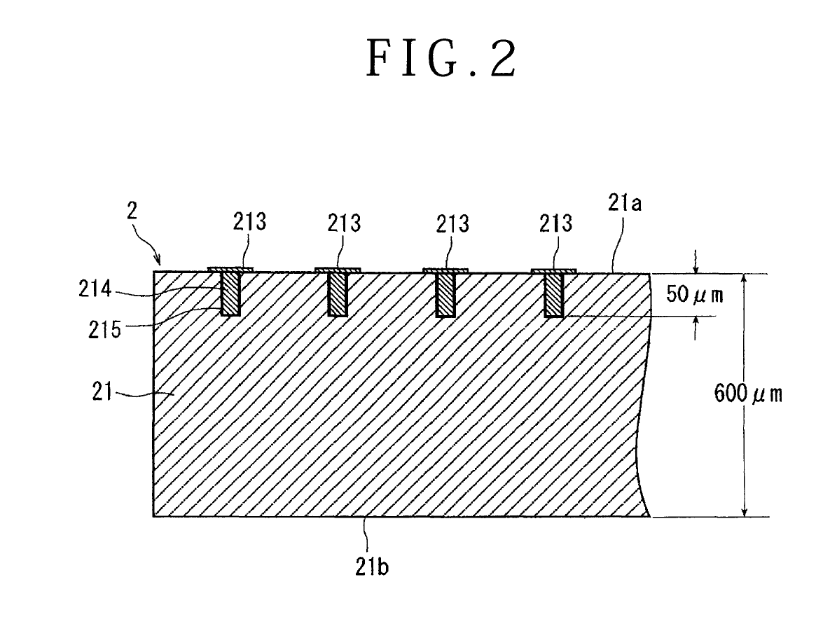

A preferred embodiment of the wafer processing method according to the present invention will now be described in detail with reference to the attached drawings. FIG. 1 is a perspective view of a wafer 2 to be processed by the wafer processing method according to the present invention. The wafer 2 shown in FIG. 1 is formed from a silicon (Si) substrate 21 having a thickness of 600 μm, for example. The silicon (Si) substrate 21 has a front side 21a and a back side 21b. A plurality of crossing streets 211 are formed on the front side 21a of the silicon (Si) substrate 21 to thereby partition a plurality of rectangular regions where a plurality of devices 212 such as ICs and LSIs are respectively formed. A plurality of bonding pads 213 are provided on the front side of each device 212. As shown in FIG. 2, a plurality of copper (Cu) electrodes 214 respectively connected to the bonding pads 213 are embedded in the silicon (Si) substrate 21 of the wafer 2. Each copper (Cu) electrode 214 embedded in the silicon (Si) substrate 21 has a length of 50 μm, for example. Each copper (Cu) electrode 214 is covered with a silicon dioxide (SiO₂) film 215 as an insulating film having a thickness of about 150 nm, for example.

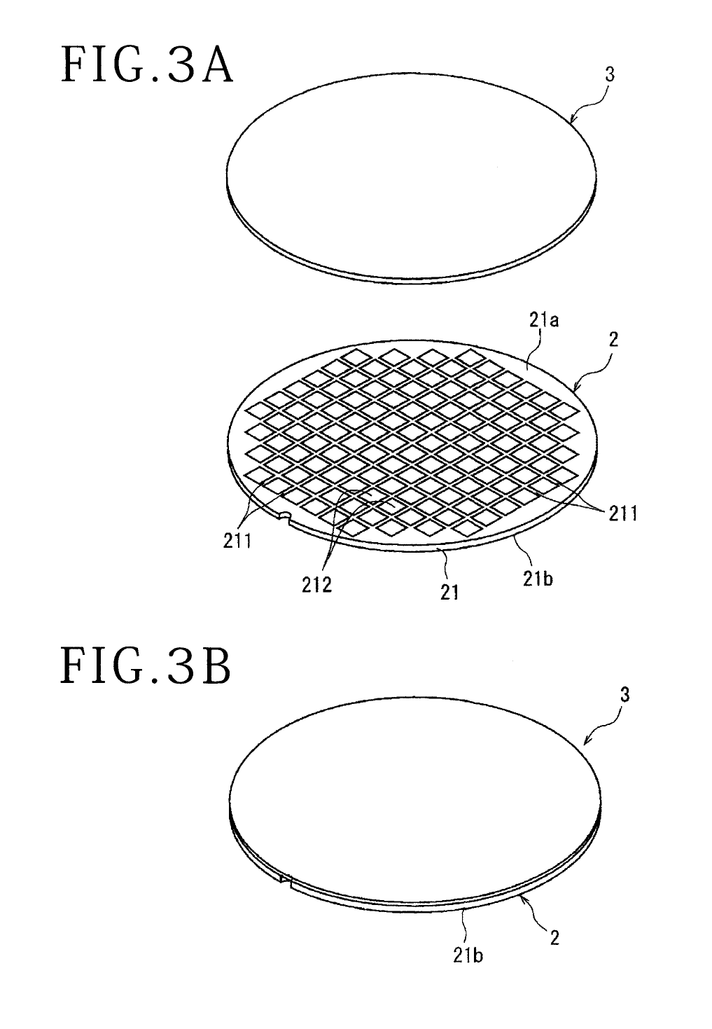

There will now be described a processing method for exposing the copper (Cu) electrodes 214 to the back side 21b of the silicon (Si) substrate 21 of the wafer 2 so that the copper (Cu) electrodes 214 project from the back side 21b. First, as shown in FIGS. 3A and 3B, a protective member attaching step is performed in such a manner that a protective member 3 such as a protective tape is attached to the front side of the wafer 2 in order to protect the devices 212 formed on the front side 21a of the silicon (Si) substrate 21 of the wafer 2.

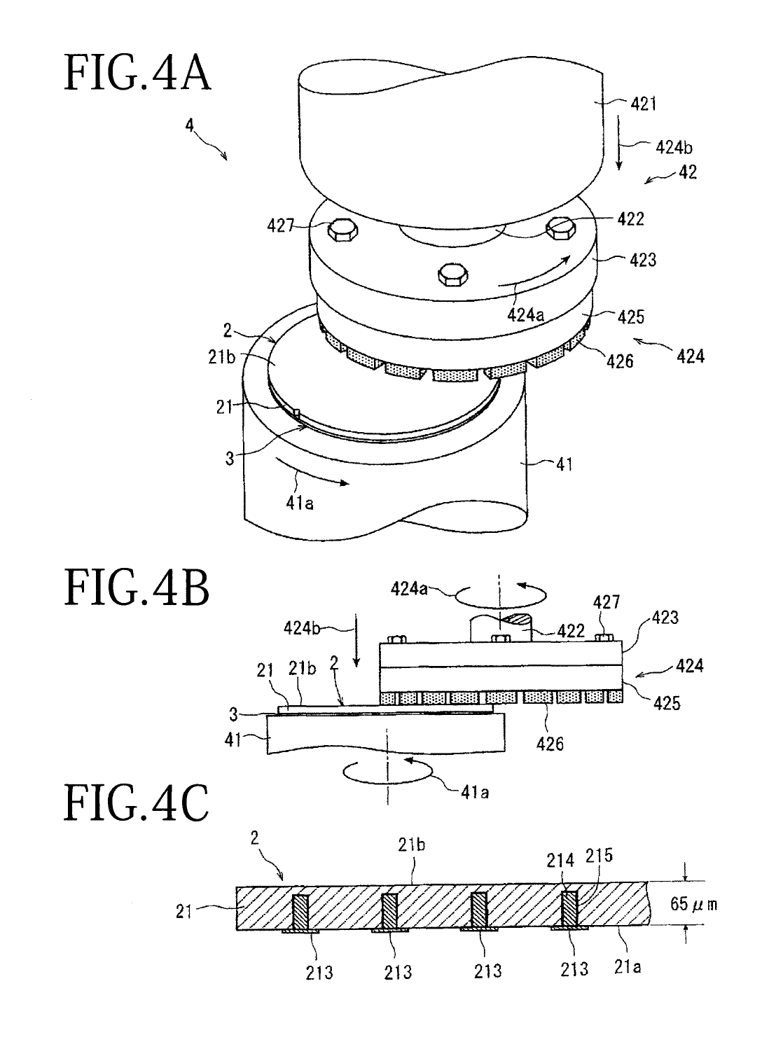

After performing the protective member attaching step mentioned above, a back grinding step is performed in such a manner that the back side 21b of the silicon (Si) substrate 21 of the wafer 2 is ground so as not to expose the copper (Cu) electrodes 214. This back grinding step is performed by using a grinding apparatus 4 essentially shown in FIG. 4A. The grinding apparatus 4 shown in FIG. 4A includes a chuck table 41 for holding a workpiece and grinding means 42 for grinding the workpiece held on the chuck table 41. The chuck table 41 has an upper surface for holding the workpiece under suction. The chuck table 41 is rotatable in the direction shown by an arrow 41a in FIG. 4A. The grinding means 42 includes a spindle housing 421, a spindle 422 rotatably supported to the spindle housing 421 so as to be rotated by a rotational driving mechanism (not shown), a mounter 423 mounted on the lower end of the spindle 422, a grinding wheel 424 mounted on the lower surface of the mounter 423. The grinding wheel 424 is composed of an annular base 425 and a plurality of abrasive members 426 mounted on the lower surface of the base 425 so as to be annularly arranged along the outer circumference of the base 425. The base 425 is mounted to the lower surface of the mounter 423 by a plurality of fastening bolts 427.

The back grinding step using this grinding apparatus 4 is performed in the following manner. First, the wafer 2 is placed on the chuck table 41 in the condition where the protective member 3 attached to the front side of the wafer 2 comes into contact with the upper surface (holding surface) of the chuck table 41 as shown in FIG. 4A. In this condition, suction means (not shown) is operated to hold the wafer 2 through the protective member 3 on the chuck table 41 under suction. Accordingly, the back side 21b of the silicon (Si) substrate 21 of the wafer 2 held through the protective member 3 on the chuck table 41 is oriented upward. In the condition where the wafer 2 is held under suction on the chuck table 41 as mentioned above, the chuck table 41 is rotated at 300 rpm, for example, in the direction shown by the arrow 41a in FIG. 4A and the grinding wheel 424 of the grinding means 42 is also rotated at 6000 rpm, for example, in the direction shown by an arrow 424a in FIG. 4A. Thereafter, the grinding wheel 424 is lowered to bring the grinding surfaces (lower surfaces) of the abrasive members 426 into contact with the back side 21b of the silicon (Si) substrate 21 as a work surface as shown in FIG. 4B. Thereafter, the grinding wheel 424 is fed downward (in the direction perpendicular to the holding surface of the chuck table 41 as shown by an arrow 424b in FIGS. 4A and 4B) at a predetermined feed speed (e.g., 3 μm/sec) by an amount of 535 μm, for example. At this time, a grinding water is supplied to a work portion to be ground by the abrasive members 426 of the grinding wheel 424. In this back grinding step, the back side 21b of the silicon (Si) substrate 21 of the wafer 2 is ground by the amount of 535 μm, for example. Accordingly, the thickness of the silicon (Si) substrate 21 of the wafer 2 is reduced to 65 μm by this back grinding step as shown in FIG. 4C. Since the length of each copper (Cu) electrode 214 is 50 μm as mentioned above, each copper (Cu) electrode 214 is not exposed to the back side 21b of the silicon (Si) substrate 21 in the condition shown in FIG. 4C.

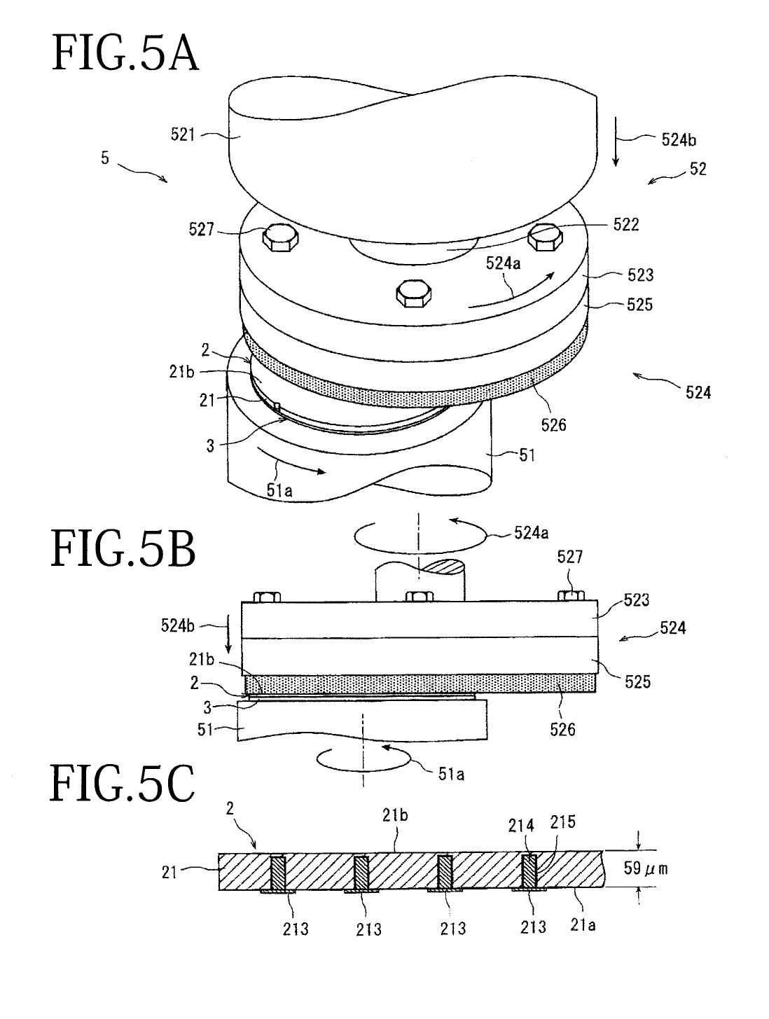

After performing the back grinding step mentioned above, a polishing step is performed to remove a saw mark formed on the back side 21b of the silicon (Si) substrate 21 in the back grinding step, planarizing the back side 21b of the silicon (Si) substrate 21. This polishing step is performed by using a polishing apparatus 5 shown in FIG. 5A. The polishing apparatus 5 shown in FIG. 5A includes a chuck table 51 for holding a workpiece and polishing means 52 for polishing the workpiece held on the chuck table 51. The chuck table 51 has an upper surface for holding the workpiece under suction. The chuck table 51 is rotatable in the direction shown by an arrow 51a in FIG. 5A. The polishing means 52 includes a spindle housing 521, a spindle 522 rotatably supported to the spindle housing 521 so as to be rotated by a rotational driving mechanism (not shown), a mounter 523 mounted on the lower end of the spindle 522, and a polishing tool 524 mounted on the lower surface of the mounter 523. The polishing tool 524 is composed of a circular base 525 and an annular polishing pad 526 mounted on the lower surface of the base 525. The base 525 is mounted to the lower surface of the mounter 523 by a plurality of fastening bolts 527.

The polishing step using the polishing apparatus 5 is performed in the following manner. First, the wafer 2 is placed on the chuck table 51 in the condition where the protective member 3 attached to the front side of the wafer 2 comes into contact with the upper surface (holding surface) of the chuck table 51 as shown in FIG. 5A after performing the back grinding step. In this condition, suction means (not shown) is operated to hold the wafer 2 through the protective member 3 on the chuck table 51 under suction. Accordingly, the back side 21b of the silicon (Si) substrate 21 of the wafer 2 held through the protective member 3 on the chuck table 51 is oriented upward. In the condition where the wafer 2 is held under suction on the chuck table 51 as mentioned above, the chuck table 51 is rotated at 300 rpm, for example, in the direction shown by the arrow 51a in FIG. 5A and the polishing tool 524 of the polishing means 52 is also rotated at 3000 rpm, for example, in the direction shown by an arrow 524a in FIG. 5A. Thereafter, the polishing tool 524 is lowered to bring the polishing surface (lower surface) of the polishing pad 526 into contact with the back side 21b of the silicon (Si) substrate 21 as a work surface as shown in FIG. 5B. Thereafter, the grinding tool 524 is pressed in the direction shown by an arrow 524b in FIGS. 5A and 5B at a polishing pressure of 10 newtons. At this time, a polishing liquid is supplied to a contact portion between the polishing surface of the polishing pad 526 and the back side 21b of the silicon (Si) substrate 21. In this polishing step, the back side 21b of the silicon (Si) substrate 21 of the wafer 2 is polished by an amount of 6 μm, for example. Accordingly, the thickness of the silicon (Si) substrate 21 of the wafer 2 is reduced to 59 μm by this polishing step as shown in FIG. 5C. Since the length of each copper (Cu) electrode 214 is 50 μm as mentioned above, each copper (Cu) electrode 214 is not exposed to the back side 21b of the silicon (Si) substrate 21 in the condition shown in FIG. 5C.

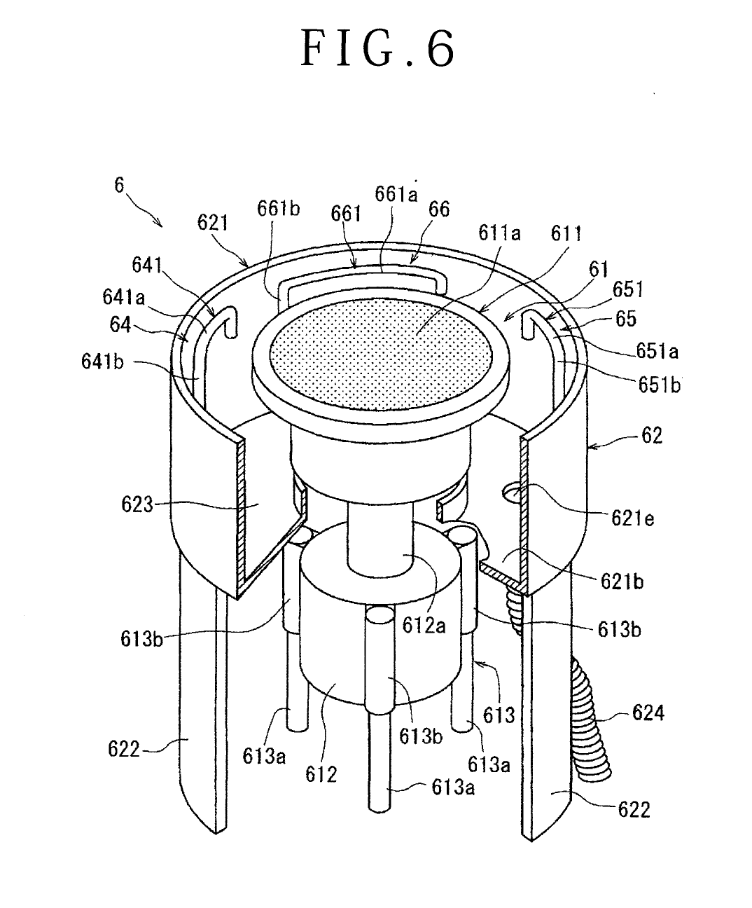

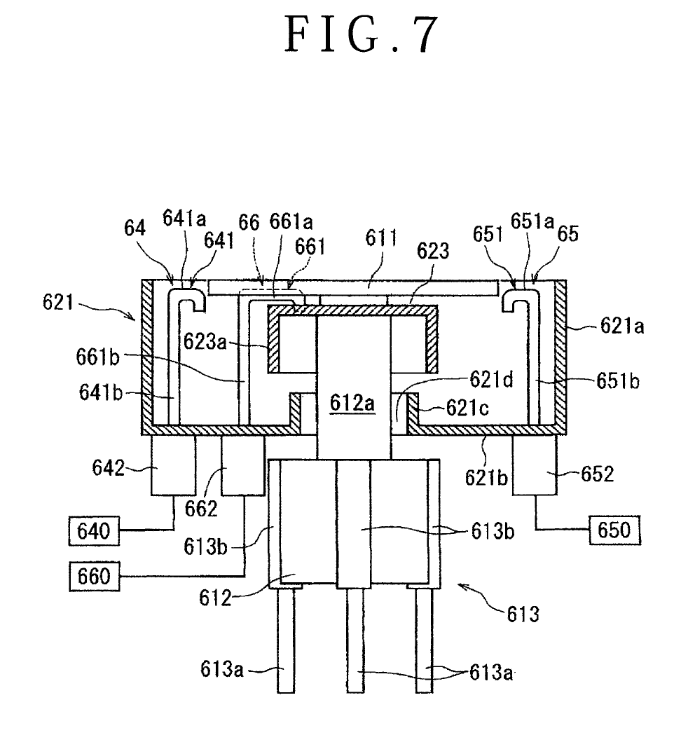

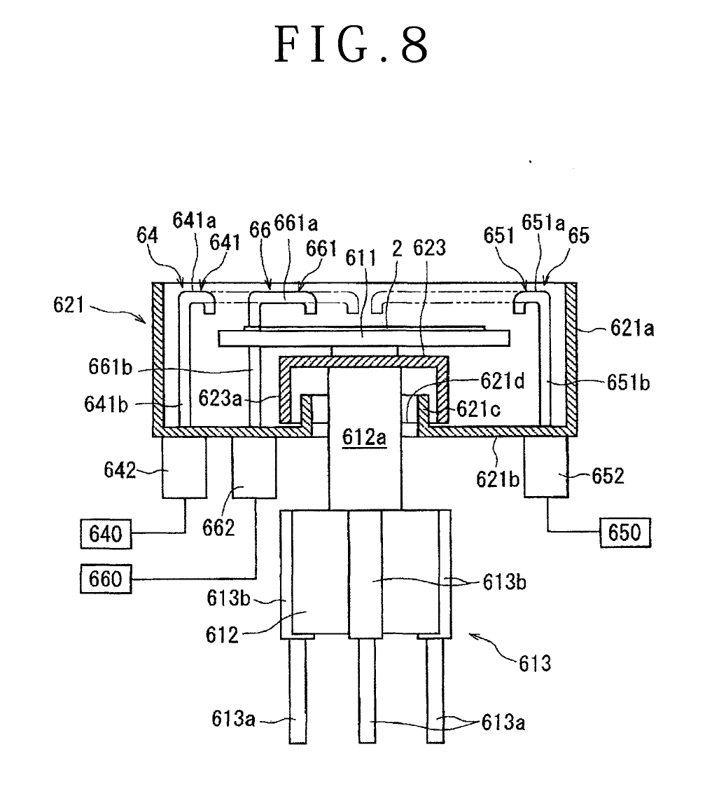

After performing the polishing step mentioned above, an etching step is performed in such a manner that the back side 21b of the silicon (Si) substrate 21 of the wafer 2 is etched by an etching liquid to thereby expose the copper (Cu) electrodes 214 to the back side 21b of the silicon (Si) substrate 21. This etching step is performed by using an etching apparatus 6 shown in FIG. 6. The etching apparatus 6 shown in FIG. 6 includes a spinner table mechanism 61 and spinner table accommodating means 62 provided so as to surround the spinner table mechanism 61. The spinner table mechanism 61 includes a spinner table 611, an electric motor 612 as rotationally driving means for rotationally driving the spinner table 611, and supporting means 613 for vertically movably supporting the electric motor 612. The spinner table 611 includes a vacuum chuck 611a formed of a porous material. The vacuum chuck 611a is connected to suction means (not shown). Accordingly, the spinner table 611 functions to hold the wafer 2 as a workpiece placed on the vacuum chuck 611a by using a vacuum produced by the suction means. The electric motor 612 has a drive shaft 612a, and the spinner table 611 is connected to the upper end of the drive shaft 612a. The supporting means 613 is composed of a plurality of (three in this preferred embodiment) support legs 613a and a plurality of (three in this preferred embodiment) air cylinders 613b operatively connected to the support legs 613a, respectively. All of the air cylinders 613b are mounted on the electric motor 612. The supporting means 613 functions in such a manner that the air cylinders 613b are operated to vertically move the electric motor 612 and the spinner table 611 between the upper position shown in FIG. 6 and FIG. 7 as a work load/unload position and the lower position shown in FIG. 8 as a working position.

The spinner table accommodating means 62 includes a receptacle 621, three support legs 622 for supporting the receptacle 621 (two of the three support legs 622 being shown in FIG. 6), and a cover member 623 mounted on the drive shaft 612a of the electric motor 612. As shown in FIGS. 7 and 8, the receptacle 621 is composed of a cylindrical outer wall 621a, a bottom wall 621b, and a cylindrical inner wall 621c. The bottom wall 621b is formed with a central hole 621d for allowing the insertion of the drive shaft 612a of the electric motor 612. The cylindrical inner wall 621c projects upward from the peripheral edge of the central hole 621d. As shown in FIG. 6, the bottom wall 621b is formed with a waste fluid outlet 621e, and a drain hose 624 is connected to the waste fluid outlet 621e. The cover member 623 is a cylindrical member having a closed top. The closed top of the cover member 623 is mounted to the upper end portion of the drive shaft 612a of the electric motor 612, and a covering portion 623a projects downward from the outer circumference of the closed top of the cover member 623. In the working position of the electric motor 612 and the spinner table 611 as shown in FIG. 8, the covering portion 623a of the cover member 623 is located so as to surround the cylindrical inner wall 621c of the receptacle 621 with a given gap defined therebetween.

The etching apparatus 6 further includes a first etching liquid supplying mechanism 64 for supplying a first etching liquid to the workpiece held on the spinner table 611. The first etching liquid supplying mechanism 64 includes a first etching liquid supplying nozzle 641 for supplying the first etching liquid toward the workpiece held on the spinner table 611 and a reversible electric motor 642 (see FIGS. 7 and 8) for swinging the first etching liquid supplying nozzle 641. As shown in FIGS. 7 and 8, the first etching liquid supplying nozzle 641 is connected to first etching liquid supplying means 640. The first etching liquid supplying nozzle 641 is composed of a horizontally extending nozzle portion 641a and a support portion 641b extending downward from the base end of the nozzle portion 641a. The support portion 641b is inserted through a hole (not shown) formed through the bottom wall 621b of the receptacle 621 and is connected to the first etching liquid supplying means 640 (see FIGS. 7 and 8). Although not shown, a seal member is mounted to the peripheral edge of the insert hole of the bottom wall 621b for allowing the insertion of the support portion 641b of the first etching liquid supplying nozzle 641, thereby sealing the gap between the support portion 641b and the bottom wall 621b. The first etching liquid supplying means 640 is provided to supply a mixture of hydrofluoric acid (HF) and nitric acid (HNO₃) or potassium hydroxide (KOH) as the first etching liquid.

The etching apparatus 6 further includes a second etching liquid supplying mechanism 65 for supplying a second etching liquid to the workpiece held on the spinner table 611. The second etching liquid supplying mechanism 65 includes a second etching liquid supplying nozzle 651 for supplying the second etching liquid toward the workpiece held on the spinner table 611 and a reversible electric motor 652 (see FIGS. 7 and 8) for swinging the second etching liquid supplying nozzle 651. As shown in FIGS. 7 and 8, the second etching liquid supplying nozzle 651 is connected to second etching liquid supplying means 650. The second etching liquid supplying nozzle 651 is composed of a horizontally extending nozzle portion 651a and a support portion 651b extending downward from the base end of the nozzle portion 651a. The support portion 651b is inserted through a hole (not shown) formed through the bottom wall 621b of the receptacle 621 and is connected to the second etching liquid supplying means 650 (see FIGS. 7 and 8). Although not shown, a seal member is mounted to the peripheral edge of the insert hole of the bottom wall 621b for allowing the insertion of the support portion 651b of the second etching liquid supplying nozzle 651, thereby sealing the gap between the support portion 651b and the bottom wall 621b. The second etching liquid supplying means 650 is provided to supply tetramethylammonium hydroxide (TMAH) as the second etching liquid.

The etching apparatus 6 further includes a cleaning water supplying mechanism 66 for supplying a cleaning water to the workpiece held on the spinner table 611. The cleaning water supplying mechanism 66 includes a cleaning water supplying nozzle 661 for supplying the cleaning water toward the workpiece held on the spinner table 611 and a reversible electric motor 662 (see FIGS. 7 and 8) for swinging the cleaning water supplying nozzle 661. As shown in FIGS. 7 and 8, the cleaning water supplying nozzle 661 is connected to cleaning water supplying means 660. The cleaning water supplying nozzle 661 is composed of a horizontally extending nozzle portion 661a having a downward bent front end and a support portion 661b extending downward from the base end of the nozzle portion 661a. The support portion 661b is inserted through a hole (not shown) formed through the bottom wall 621b of the receptacle 621 and is connected to the cleaning water supplying means 660 (see FIGS. 7 and 8). Although not shown, a seal member is mounted to the peripheral edge of the insert hole of the bottom wall 621b for allowing the insertion of the support portion 661b of the cleaning water supplying nozzle 661, thereby sealing the gap between the support portion 661b and the bottom wall 621b.

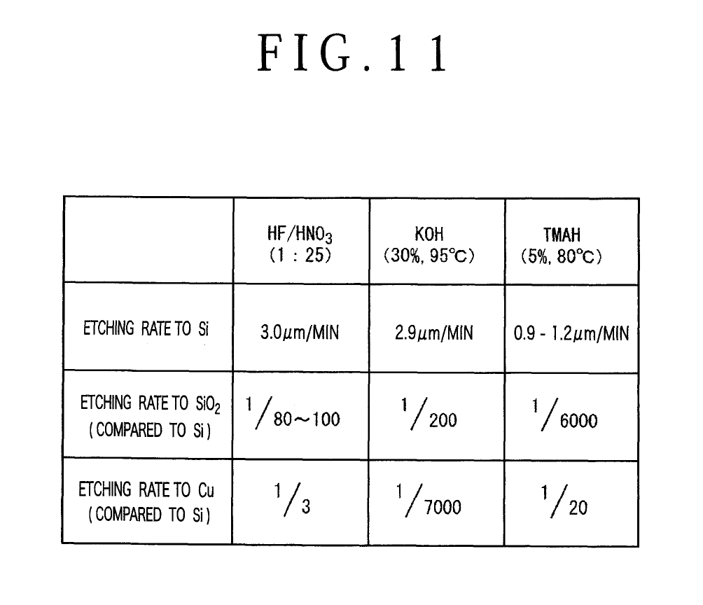

There will now be described with reference to FIG. 11 the etching rates of a mixture of hydrofluoric acid (HF) and nitric acid (HNO₃) or potassium hydroxide (KOH) to be supplied by the first etching liquid supplying means 640 of the etching apparatus 6 to silicon (Si), silicon dioxide (SiO₂), and copper (Cu) and the etching rates of tetramethylammonium hydroxide (TMAH) to be supplied by the second etching liquid supplying means 650 of the etching apparatus 6 to silicon (Si), silicon dioxide (SiO₂), and copper (Cu). As apparent from FIG. 11, the etching rate of a mixture of hydrofluoric acid (HF) and nitric acid (HNO₃) to silicon (Si) is high, and the etching rate of potassium hydroxide (KOH) to silicon (Si) is also high. On the other hand, the etching rate of tetramethylammonium hydroxide (TMAH) to silicon (Si) is not so high as that of a mixture of hydrofluoric acid (HF) and nitric acid (HNO₃) or potassium hydroxide (KOH). However, tetramethylammonium hydroxide (TMAH) is capable of etching silicon (Si) and its etching rate to silicon dioxide (SiO₂) is very low.

The etching step to be performed by using the etching apparatus 6 will now be described. First, the wafer 2 (with the protective member 3 attached to the front side) polished by the polishing step mentioned above is placed on the vacuum chuck 611a of the spinner table 611 constituting the etching apparatus 6 in the condition where the protective member 3 attached to the front side of the wafer 2 comes into contact with the vacuum chuck 611a. In this condition, the suction means is operated to hold the wafer 2 through the protective member 3 on the vacuum chuck 611a under suction. Accordingly, the back side 21b of the silicon (Si) substrate 21 of the wafer 2 held through the protective member 3 on the vacuum chuck 611a is oriented upward. At this time, the spinner table 611 is set at the load/unload position shown in FIG. 7, and all of the first etching liquid supplying nozzle 641, the second etching liquid supplying nozzle 651, and the cleaning water supplying nozzle 661 are set at the their standby positions where they are retracted from the spinner table 611 as shown in FIGS. 7 and 8.

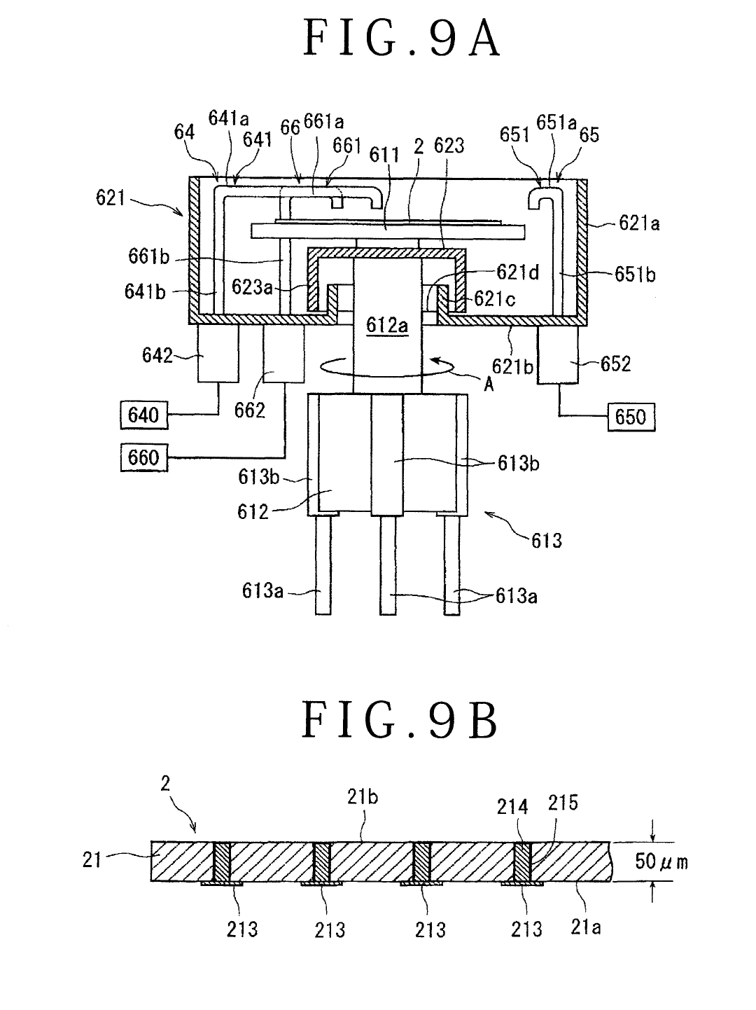

After holding the wafer 2 through the protective member 3 on the vacuum chuck 611a of the spinner table 611 under suction as mentioned above, a first etching step is performed in such a manner that the back side 21b of the silicon (Si) substrate 21 is etched by using the first etching liquid having a high etching rate to silicon (Si) to thereby incompletely expose the copper (Cu) electrodes 214 covered with the silicon dioxide (SiO₂) film 215 to the back side 21b of the silicon (Si) substrate 21. In performing the first etching step, the spinner table 611 is lowered to the working position in the condition where the wafer 2 is held through the protective member 3 on the vacuum chuck 611a under suction, and the nozzle portion 641a of the first etching liquid supplying nozzle 641 is swiveled about the axis of the support portion 641b so that the front end of the nozzle portion 641a comes to a position directly above the center of the back side 21b of the silicon (Si) substrate 21 of the wafer 2 held on the spinner table 611 as shown in FIG. 9A. Thereafter, the electric motor 612 is operated to rotate the spinner table 611 in the direction shown by an arrow A in FIG. 9A at a rotational speed of 100 rpm, for example, and the first etching liquid supplying means 640 is operated to supply a mixture of hydrofluoric acid (HF) and nitric acid (HNO₃) to the first etching liquid supplying nozzle 641 at a rate of one liter per minute (1 liter/min). Accordingly, the mixture of hydrofluoric acid (HF) and nitric acid (HNO₃) thus supplied to the first etching liquid supplying nozzle 641 is supplied from the nozzle portion 641a to the center of the back side 21b of the silicon (Si) substrate 21 of the wafer 2 held on the spinner table 611.

The mixture of hydrofluoric acid (HF) and nitric acid (HNO₃) supplied to the center of the back side 21b of the silicon (Si) substrate 21 is spread toward the outer circumference of the wafer 2 by a centrifugal force to thereby etch the back side 21b of the silicon (Si) substrate 21. The first etching step is performed for three minutes, so that the back side 21b of the silicon (Si) substrate 21 is etched by an amount of 9 μm, for example, thereby reducing the thickness of the wafer 2 to 50 μm, for example, as shown in FIG. 9B. As a result, the copper (Cu) electrodes 214 covered with the silicon dioxide (SiO₂) film 215 are slightly exposed to the back side 21b of the silicon (Si) substrate 21. While a mixture of hydrofluoric acid (HF) and nitric acid (HNO₃) is used as the first etching liquid in the first etching step in this preferred embodiment, potassium hydroxide (KOH) having a high etching rate to silicon (Si) may be used as the first etching liquid in the first etching step according to the present invention.

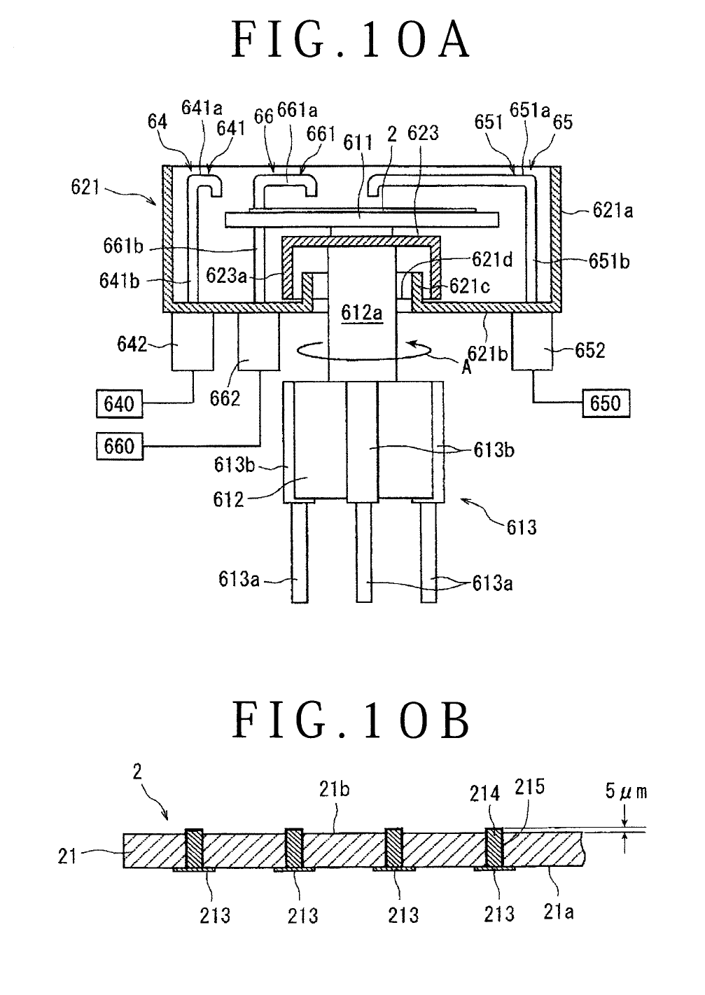

After performing the first etching step mentioned above, a second etching step is performed in such a manner that the back side 21b of the silicon (Si) substrate 21 is etched by using the second etching liquid capable of etching silicon (Si) and having a low etching rate to silicon dioxide (SiO₂) to thereby project the copper (Cu) electrodes 214 covered with the silicon dioxide (SiO₂) film 215 from the back side 21b of the silicon (Si) substrate 21. In performing the second etching step, the first etching liquid supplying nozzle 641 is retracted to the standby position and the nozzle portion 651a of the second etching liquid supplying nozzle 651 is swiveled about the axis of the support portion 651b so that the front end of the nozzle portion 651a comes to a position directly above the center of the back side 21b of the silicon (Si) substrate 21 of the wafer 2 held on the spinner table 611 as shown in FIG. 10A. Thereafter, the electric motor 612 is operated to rotate the spinner table 611 in the direction shown by an arrow A in FIG. 10A at a rotational speed of 100 rpm, for example, and the second etching liquid supplying means 650 is operated to supply tetramethylammonium hydroxide (TMAH) to the second etching liquid supplying nozzle 651 at a rate of one liter per minute (1 liter/min). Accordingly, the tetramethylammonium hydroxide (TMAH) thus supplied to the second etching liquid supplying nozzle 651 is supplied from the nozzle portion 651a to the center of the back side 21b of the silicon (Si) substrate 21 of the wafer 2 held on the spinner table 611.

The tetramethylammonium hydroxide (TMAH) supplied to the center of the back side 21b of the silicon (Si) substrate 21 is spread toward the outer circumference of the wafer 2 by a centrifugal force to thereby etch the back side 21b of the silicon (Si) substrate 21. The second etching step is performed for five minutes, so that the back side 21b of the silicon (Si) substrate 21 is etched by an amount of 5 μm, for example. As a result, the copper (Cu) electrodes 214 covered with the silicon dioxide (SiO₂) film 215 projects by the amount of 5 μm from the back side 21b of the silicon (Si) substrate 21. The tetramethylammonium hydroxide (TMAH) used as the second etching liquid in the second etching step can etch silicon (Si) and has a low etching rate to silicon dioxide (SiO₂). Further, etching time is short in the second etching step. Accordingly, the etching amount of the silicon dioxide (SiO₂) film 215 covering the copper (Cu) electrodes 214 is small, so that the copper (Cu) electrodes 214 are not etched to be maintained.

After performing the second etching step mentioned above, a cleaning step of cleaning the wafer 2 etched above is performed. In performing the cleaning step, the second etching liquid supplying nozzle 651 is retracted to the standby position and the nozzle portion 661a of the cleaning water supplying nozzle 661 is swiveled about the axis of the support portion 661b so that the front end of the nozzle portion 661a comes to a position directly above the center of the back side 21b of the silicon (Si) substrate 21 of the wafer 2 held on the spinner table 661. Thereafter, the electric motor 612 is operated to rotate the spinner table 611 at a rotational speed of 800 rpm, for example, and the cleaning water supplying means 660 is operated to supply a cleaning water from the nozzle portion 661a of the cleaning water supplying nozzle 661 to the back side 21b of the silicon (Si) substrate 21. The nozzle portion 661a is preferably provided by a so-called two-fluid nozzle such that about 0.2 MPa of water and about 0.3 to 0.5 MPa of air are supplied and the water is sprayed by the pressure of the air to effectively clean the back side 21b of the silicon (Si) substrate 21 of the wafer 2. At this time, the electric motor 662 is operated to swing the nozzle portion 661a of the cleaning water supplying nozzle 661 in a required angular range from the center of the wafer 2 to the outer circumference thereof. As a result, the back side 21b of the silicon (Si) substrate 21 of the wafer 2 can be reliably cleaned.

After performing the cleaning step mentioned above, the rotation of the spinner table 611 is stopped and the cleaning water supplying nozzle 661 is retracted to the standby position. Thereafter, the spinner table 611 is raised to the load/unload position shown in FIG. 7, and the suction holding of the wafer 2 on the spinner table 611 is canceled. Thereafter, the wafer 2 is carried from the spinner table 611 to a location for the next step by any suitable carrying means.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method for processing a wafer including a silicon (Si) substrate and a plurality of devices formed on a front side of said silicon (Si) substrate, wherein each device is provided with a bonding pad, and an electrode covered with a silicon dioxide (SiO₂) film is embedded in said silicon (Si) substrate so as to be connected to said bonding pad, said wafer processing method comprising:
a protective member attaching step of attaching a protective member to a front side of said wafer;
a back grinding step of grinding a back side of said silicon (Si) substrate of said wafer so as not to expose said electrode to the back side of said silicon (Si) substrate after performing said protective member attaching step; and
an etching step of etching the back side of said silicon (Si) substrate by using an etching liquid to thereby expose said electrode to the back side of said silicon (Si) substrate after performing said back grinding step;
said etching liquid including a first etching liquid having a high etching rate to silicon (Si) and a second etching liquid capable of etching silicon (Si) and having a low etching rate to silicon dioxide (SiO₂); and
said etching step having
a first etching step of etching the back side of said silicon (Si) substrate by using said first etching liquid to thereby incompletely expose said electrode covered with said silicon dioxide (SiO₂) film to the back side of said silicon (Si) substrate, and
a second etching step of etching the back side of said silicon (Si) substrate by using said second etching liquid to thereby project said electrode covered with said silicon dioxide (SiO₂) film from the back side of said silicon (Si) substrate after performing said first etching step.

2. The wafer processing method according to claim 1, wherein
said electrode is formed of copper (Cu);
said first etching liquid includes a mixture of hydrofluoric acid (HF) and nitric acid (HNO₃); and said second etching liquid includes tetramethylammonium hydroxide (TMAH).

3. The wafer processing method according to claim 1, wherein
said electrode is formed of copper (Cu);
said first etching liquid includes potassium hydroxide (KOH); and said second etching liquid includes tetramethylammonium hydroxide (TMAH).

4. The wafer processing method according to claim 1, further comprising:
a polishing step of polishing the back side of said silicon (Si) substrate so as not to expose said electrode to the back side of said silicon (Si) substrate after performing said back grinding step and before performing said etching step, thereby removing a saw mark formed on the back side of said silicon (Si) substrate in said back grinding step.
